(19) United States
(12) Patent Application Publication
(10) Pub. No.: US 2025/0331426 A1
(43) Pub. Date: Oct. 23, 2025

(54) MAGNETIC MEMORY DEVICE INCLUDING A MAGNETIC TUNNEL JUNCTION

(71) Applicant: SAMSUNG ELECTRONICS CO., LTD., SUWON-SI (KR)

(72) Inventors: KI WOONG KIM, Suwon-si (KR); JEONGCHUN RYU, Suwon-si (KR); KWANG SEOK KIM, Suwon-si (KR); SEONGGEON PARK, Suwon-si (KR); SEUNGJAE LEE, Suwon-si (KR)

(21) Appl. No.: 18/921,055

(22) Filed: Oct. 21, 2024

(30) Foreign Application Priority Data
Apr. 23, 2024 (KR) 10-2024-0054025

(51) Int. Cl. H10N 50/10; H10B 61/00; H10N 50/01

(52) U.S. Cl. CPC H10N 50/10; H10B 61/22; H10N 50/01

(57) ABSTRACT

A magnetic memory device includes: a pinned magnetic pattern and a free magnetic pattern stacked on a substrate; a tunnel barrier pattern disposed between the pinned magnetic pattern and the free magnetic pattern; a capping pattern disposed on the free magnetic pattern; and a metal oxide pattern disposed between the free magnetic pattern and the capping pattern, wherein the capping pattern includes a first capping pattern and a second capping pattern that is disposed on the first capping pattern, wherein the first capping pattern includes a first non-magnetic metal, wherein the second capping pattern includes a second non-magnetic metal, and wherein the first capping pattern includes an oxide of the first non-magnetic metal that is adjacent to an interface that is between the metal oxide pattern and the first capping pattern.

### CROSS-REFERENCE TO RELATED APPLICATION

This U.S. non-provisional patent application claims priority under 35 U.S.C. § 119 to Korean Patent Application No. 10-2024-0054025, filed on Apr. 23, 2024, in the Korean Intellectual Property Office, the disclosure of which is incorporated by reference herein in its entirety.

### TECHNICAL FIELD

The present inventive concept relates to a magnetic memory device, and more particularly, to a magnetic memory device including a magnetic tunnel junction.

### DISCUSSION OF THE RELATED ART

High speed and/or low voltage semiconductor memory devices have been desired with the development of high speed and/or low power consumption electronic devices including semiconductor memory devices. To satisfy these desires, a magnetic memory device has been suggested. Generally, the magnetic memory device has high speed and/or non-volatile characteristics, and is believed to be a next generation semiconductor memory device.

Generally, the magnetic memory device may include a magnetic tunnel junction (MTJ) pattern. The MTJ pattern may include two magnetic layers and an insulating layer disposed therebetween. A resistance value of the MTJ pattern may be changed depending on magnetization directions of the two magnetic layers. For example, when the magnetization directions of the two magnetic layers are anti-parallel to each other, the MTJ pattern may have a high resistance value. Further to that example, when the magnetization directions of the two magnetic layers are parallel to each other, the MTJ pattern may have a low resistance value. Logical data may be written/read by using a difference between the high and low resistance values of the MTJ pattern.

Highly integrated and/or low power consumption magnetic memory devices have been increasingly desired with the development of an electronic industry. Thus, magnetic memory devices that are capable of satisfying these desires are currently under development.

### SUMMARY

According to embodiments of the present inventive concept, a magnetic memory device includes: a pinned magnetic pattern and a free magnetic pattern stacked on a substrate; a tunnel barrier pattern disposed between the pinned magnetic pattern and the free magnetic pattern; a capping pattern disposed on the free magnetic pattern; and a metal oxide pattern disposed between the free magnetic pattern and the capping pattern, wherein the capping pattern includes a first capping pattern and a second capping pattern that is disposed on the first capping pattern, wherein the first capping pattern includes a first non-magnetic metal, wherein the second capping pattern includes a second non-magnetic metal, and wherein the first capping pattern includes an oxide of the first non-magnetic metal that is adjacent to an interface that is between the metal oxide pattern and the first capping pattern.

According to embodiments of the present inventive concept, a magnetic memory device includes: a pinned magnetic pattern and a free magnetic pattern stacked on a substrate; a tunnel barrier pattern disposed between the pinned magnetic pattern and the free magnetic pattern; a first capping pattern and a second capping pattern stacked on the free magnetic pattern; and a metal oxide pattern disposed between the free magnetic pattern and the first capping pattern, wherein the first capping pattern includes molybdenum (Mo), and wherein the second capping pattern includes rhenium (Re).

According to embodiments of the present inventive concept, a magnetic memory device includes: a lower electrode disposed on a substrate; a pinned magnetic pattern and a free magnetic pattern stacked on the lower electrode; a tunnel barrier pattern disposed between the pinned magnetic pattern and the free magnetic pattern; a capping pattern disposed on the tunnel barrier pattern; a metal oxide pattern disposed between the capping pattern and the tunnel barrier pattern; and an upper electrode disposed on the capping pattern, wherein the capping pattern includes: a first capping pattern including a first non-magnetic metal; and a second capping pattern including a second non-magnetic metal on the first capping pattern, wherein an oxide formation energy of the first non-magnetic metal is lower than an oxide formation energy of the second non-magnetic metal, and wherein a thickness of the first capping pattern is smaller than a thickness of the second capping pattern.

### BRIEF DESCRIPTION OF THE DRAWINGS

The above and other aspects of the present inventive concept will become more apparent by describing in detail embodiments thereof, with reference to the accompanying drawings, in which:

FIG. 1 is a circuit diagram illustrating a unit memory cell of a magnetic memory device according to embodiments of the present inventive concept.

FIG. 2 is a cross-sectional view of a magnetic memory device according to embodiments of the present inventive concept.

FIG. 3 is an enlarged view of region ‘X’ in FIG. 2.

FIGS. 4 and 5 are cross-sectional views of magnetic memory devices according to embodiments of the present inventive concept.

FIG. 6 is a plan view of a magnetic memory device according to an embodiment of the present inventive concept.

FIG. 7 is a cross-sectional view of a magnetic memory device according to an embodiment of the present inventive concept, taken along line A-A′ of FIG. 6.

FIG. 8 is a plan view of a magnetic memory device according to an embodiment of the present inventive concept.

FIG. 9 is a cross-sectional view of a magnetic memory device according to an embodiment of the present inventive concept, taken along line B-B′ of FIG. 8.

FIGS. 10, 11 and 12 are cross-sectional views taken along line A-A′ of FIG. 6 to illustrate a method of manufacturing a magnetic memory device according to embodiments of the present inventive concept.

### DETAILED DESCRIPTION OF THE EMBODIMENTS

Hereinafter, embodiments of the present inventive concept will be described with reference to the attached drawings. The same reference numerals may refer to the same elements throughout the specification and drawings, and thus their descriptions that are redundant may be omitted.

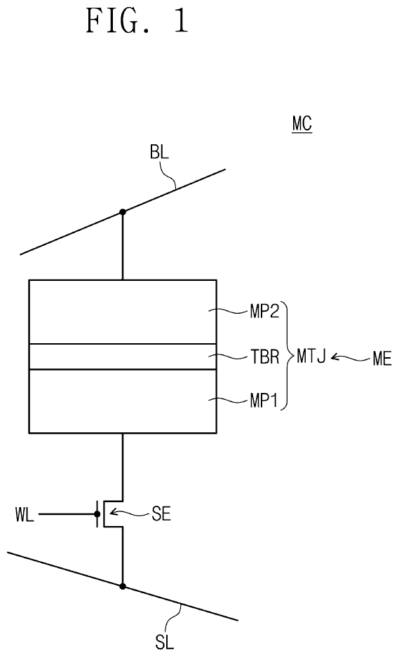

FIG. 1 is a circuit diagram illustrating a unit memory cell of a magnetic memory device according to embodiments of the present inventive concept.

Referring to FIG. 1, a unit memory cell MC may include a memory device ME and a selection device SE. The memory device ME and the selection device SE may be electrically connected to each other in series. The memory device ME may be connected between a bit line BL and a selection device SE. The selection device SE may be connected between the memory device ME and a source line SL and may be controlled by the word line WL. For example, the selection device SE may include a bipolar transistor or a MOS field effect transistor.

The memory device ME may include a magnetic tunnel junction pattern MTJ, and the magnetic tunnel junction pattern MTJ may include a first magnetic pattern MP1, a second magnetic pattern MP2, and a tunnel barrier pattern TBR that is disposed between the first magnetic pattern MP1 and the second magnetic pattern MP2. One of the first magnetic pattern MP1 or the second magnetic pattern MP2 may be a pinned magnetic pattern having a magnetization direction that is pinned in one direction regardless of an external magnetic field under a normal use environment. The other of the first magnetic pattern MP1 and the second magnetic pattern MP2 may be a free magnetic pattern whose magnetization direction changes between two stable magnetization directions due to an external magnetic field. An electrical resistance of the magnetic tunnel junction pattern MTJ may be much greater when magnetization directions of the pinned magnetic pattern and the free magnetic pattern are antiparallel to each other compared to when the magnetization directions of the pinned magnetic pattern and the free magnetic pattern are parallel to each other. For example, an electrical resistance of the magnetic tunnel junction pattern MTJ may be adjusted by changing the magnetization direction of the free magnetic pattern. Accordingly, the memory device ME may store data in the unit memory cell MC by using the difference in electrical resistance depending on the magnetization directions of the pinned magnetic pattern and the free magnetic pattern.

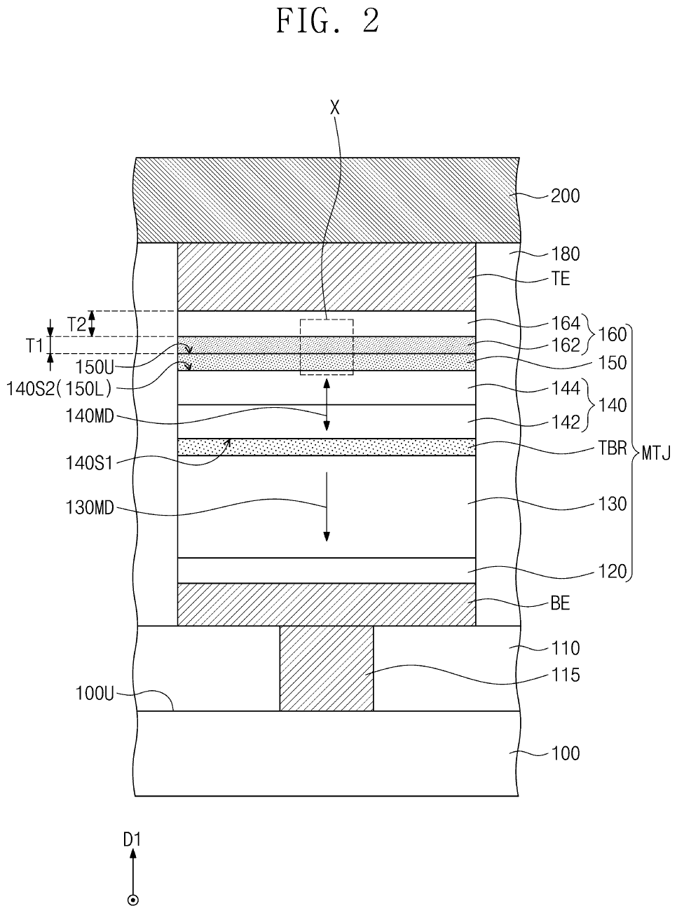

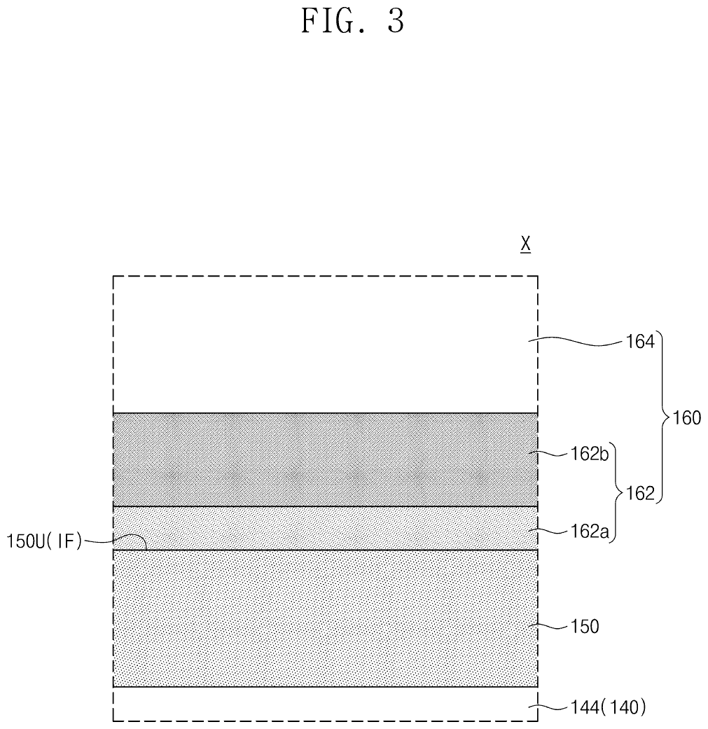

FIG. 2 is a cross-sectional view of a magnetic memory device according to embodiments of the present inventive concept. FIG. 3 is an enlarged view of region ‘X’ in FIG. 2.

Referring to FIG. 2, a first interlayer insulating layer 110 may be provided on a substrate 100. A lower contact plug 115 may be provided in the first interlayer insulating layer 110. The first interlayer insulating layer 110 may cover an upper surface 100U of the substrate 100 and side surfaces of the lower contact plug 115. For example, the substrate 100 may be a semiconductor substrate including silicon, silicon on insulator (SOI), silicon germanium (SiGe), germanium (Ge), gallium arsenide (GaAs), etc. The first interlayer insulating layer 110 may include, for example, silicon oxide, silicon nitride, and/or silicon oxynitride.

The lower contact plug 115 may penetrate the first interlayer insulating layer 110. The lower contact plug 115 may be electrically connected to the substrate 100. A selection device SE (e.g., in FIG. 1) may be provided in the substrate 100. The selection device may include a field effect transistor. The lower contact plug 115 may be electrically connected to one terminal (e.g., source/drain terminal) of the selection device. For example, the lower contact plug 115 may include at least one of a doped semiconductor material (e.g., doped silicon), a metal (e.g., tungsten, titanium, and/or tantalum), a metal-semiconductor compound (e.g., metal silicide), and a conductive material (e.g., titanium nitride, tantalum nitride, and/or tungsten nitride).

A lower electrode BE, a magnetic tunnel junction pattern MTJ, and an upper electrode TE may be provided on the lower contact plug 115. The lower electrode BE, the magnetic tunnel junction pattern MTJ, and the upper electrode TE may be sequentially stacked in a first direction D1 that is substantially perpendicular to the upper surface 100U of the substrate 100. The lower electrode BE may be disposed between the lower contact plug 115 and the magnetic tunnel junction pattern MTJ. The magnetic tunnel junction pattern MTJ may be disposed between the lower electrode BE and the upper electrode TE. The lower electrode BE may be electrically connected to the lower contact plug 115. The lower electrode BE may include a conductive metal nitride (e.g., titanium nitride or tantalum nitride). The upper electrode TE may include at least one of a metal (e.g., Ta, W, Ru, Ir, etc.) and/or a conductive metal nitride (e.g., TiN).

The magnetic tunnel junction pattern MTJ may include a pinned magnetic pattern 130, a free magnetic pattern 140, and a tunnel barrier pattern TBR that is disposed between the pinned magnetic pattern 130 and the free magnetic pattern 140. The pinned magnetic pattern 130 may be disposed between the lower electrode BE and the tunnel barrier pattern TBR. The free magnetic pattern 140 may be disposed between the upper electrode TE and the tunnel barrier pattern TBR. The magnetic tunnel junction pattern MTJ may further include a seed pattern 120, which is disposed between the lower electrode BE and the pinned magnetic pattern 130, a capping pattern 160, which is disposed between the upper electrode TE and the free magnetic pattern 140, and a metal oxide pattern 150, which is disposed between the capping pattern 160 and the free magnetic pattern 140.

The seed pattern 120 may include a material that helps crystal growth of the pinned magnetic pattern 130. For example, the seed pattern 120 may include at least one of chromium (Cr), iridium (Ir), and/or ruthenium (Ru).

The pinned magnetic pattern 130 may have a magnetization direction 130MD pinned in one direction. The magnetization direction 130MD of the pinned magnetic pattern 130 may be substantially perpendicular to an interface between the tunnel barrier pattern TBR and the free magnetic pattern 140. For example, the free magnetic pattern 140 may have a first surface 140S1 and a second surface 140S2 facing each other. The first surface 140S1 of the free magnetic pattern 140 may be adjacent to the tunnel barrier pattern TBR. For example, the first surface 140S1 of the free magnetic pattern 140 may contact the tunnel barrier pattern TBR. The second surface 140S2 of the free magnetic pattern 140 may be adjacent to the metal oxide pattern 150. For example, the second surface 140S2 of the free magnetic pattern 140 may contact the metal oxide pattern 150. The first surface 140S1 of the free magnetic pattern 140 may be an interface where the tunnel barrier pattern TBR and the free magnetic pattern 140 are in contact with each other. The second surface 140S2 of the free magnetic pattern 140 may be an interface where the metal oxide pattern 150 and the free magnetic pattern 140 are in contact with each other. The magnetization direction 130MD of the pinned magnetic pattern 130 may be substantially perpendicular to the first surface 140S1 of the free magnetic pattern 140.

The pinned magnetic pattern 130 may include a magnetic element. The pinned magnetic pattern 130 may include at least one of, for example, iron (Fe), cobalt (Co), and/or nickel (Ni). The pinned magnetic pattern 130 may include at least one of an intrinsic vertical magnetic material and/or an extrinsic vertical magnetic material.

An intrinsic perpendicular magnetic material may include a material exhibiting a perpendicular magnetization property, even when there is no external cause. For example, the intrinsic perpendicular magnetic material may include at least one of a perpendicular magnetic material (e.g., CoFeTb, CoFeGd, or CoFeDy), a perpendicular magnetic material with L₁₀ structure, a CoPt material with a hexagonal close packed lattice structure, and/or a perpendicular magnetic structure. For example, the perpendicular magnetic material with the L₁₀ structure may include at least one of L₁₀ FePt, L₁₀ FePd, L₁₀ CoPd, or L₁₀ CoPt. The perpendicular magnetic structure may include magnetic layers and non-magnetic layers that are alternatingly and repeatedly stacked on each other. For example, the perpendicular magnetic structure may include at least one of (Co/Pt) n, (CoFe/Pt) n, (CoFe/Pd) n, (Co/Pd) n, (Co/Ni) n, (CoNi/Pt) n, (CoCr/Pt) n, or (CoCr/Pd) n, where “n” is a natural number equal to or greater than 2.

An extrinsic perpendicular magnetic material may include a material, which has an intrinsic in-plane magnetization property but has a perpendicular magnetization property by an external cause. For example, the extrinsic perpendicular magnetic material may have perpendicular magnetization property due to magnetic anisotropy induced by the junction of the pinned magnetic pattern 130 and the tunnel barrier pattern TBR. For example, the extrinsic perpendicular magnetic material may include CoFeB. The pinned magnetic pattern 130 may include a Heusler alloy based on cobalt (Co).

The tunnel barrier pattern TBR may include a metal oxide layer. For example, the tunnel barrier pattern TBR may include at least one of a magnesium (Mg) oxide layer, a titanium (Ti) oxide layer, an aluminum (Al) oxide layer, a magnesium-zinc (Mg—Zn) oxide layer, or a magnesium-boron (Mg—B) oxide layer.

The free magnetic pattern 140 may have a magnetization direction 140MD that is capable of being changed to be parallel or anti-parallel to the magnetization direction 130MD of the pinned magnetic pattern 130. The magnetization direction 140MD of the free magnetic pattern 140 may be substantially perpendicular to an interface that is between the tunnel barrier pattern TBR and the free magnetic pattern 140. For example, the magnetization direction 140MD of the free magnetic pattern 140 may be substantially perpendicular to the first surface 140S1 of the free magnetic pattern 140.

According to an embodiment of the present inventive concept, the free magnetic pattern 140 may include a first free magnetic pattern 142, which is adjacent to the tunnel barrier pattern TBR, and a second free magnetic pattern 144, which is separated from the tunnel barrier pattern TBR by the first free magnetic pattern 142. The second free magnetic pattern 144 may be adjacent to the metal oxide pattern 150. The first free magnetic pattern 142 may be disposed between the tunnel barrier pattern TBR and the second free magnetic pattern 144. The second free magnetic pattern 144 may be disposed between the first free magnetic pattern 142 and the metal oxide pattern 150.

Each of the first free magnetic pattern 142 and the second free magnetic pattern 144 may include a magnetic element. For example, the first free magnetic pattern 142 may include at least one of iron (Fe), cobalt (Co), and/or nickel (Ni). For example, the first free magnetic pattern 142 may include cobalt-iron (CoFe). In addition, the first free magnetic pattern 142 may include at least one of a vertical magnetic material (e.g., CoFeTb, CoFeGd, CoFeDy), a vertical magnetic material with an L₁₀ structure, CoPt with a hexagonal close packed lattice structure, and/or a vertical magnetic material. The second free magnetic pattern 144 may include a magnetic material having perpendicular magnetization characteristics due to magnetic anisotropy that is induced at an interface that is between the second free magnetic pattern 144 and the first free magnetic pattern 142 and/or an interface that is between the second free magnetic pattern 144 and the metal oxide pattern 150. For example, the second free magnetic pattern 144 may include cobalt-iron-boron (CoFeB). Each of the first free magnetic pattern 142 and the second free magnetic pattern 144 may include a Heusler alloy based on cobalt (Co). However, the present inventive concept is not limited thereto.

The metal oxide pattern 150 may be disposed between the second free magnetic pattern 144 and the capping pattern 160. The metal oxide pattern 150 may be used to increase the perpendicular magnetic anisotropy of the free magnetic pattern 140. The metal oxide pattern 150 may have an upper surface 150U and a lower surface 150L facing each other in the first direction D1. The lower surface 150L of the metal oxide pattern 150 may correspond to the second surface 140S2 of the free magnetic pattern 140. For example, the metal oxide pattern 150 may include one of magnesium (Mg), tungsten (W), tantalum (Ta), titanium (Ti), and hafnium (Hf), or oxygen (O).

The capping pattern 160 may be disposed on the metal oxide pattern 150. The capping pattern 160 may include a first capping pattern 162, which is adjacent to the metal oxide pattern 150, and a second capping pattern 164, which is separated from the metal oxide pattern 150 by the first capping pattern 162. The first capping pattern 162 may be disposed between the metal oxide pattern 150 and the second capping pattern 164. The second capping pattern 164 may be disposed between the first capping pattern 162 and the upper electrode TE. The second capping pattern 164 may be disposed on the first capping pattern 162. For example, the first capping pattern 162 and the second capping pattern 164 may be in contact with each other.

The first capping pattern 162 and the second capping pattern 164 may have different thicknesses from each other. The first capping pattern 162 may have a first thickness T1 in the first direction D1. The second capping pattern 164 may have a second thickness T2 in the first direction D1. The first thickness T1 may be smaller than the second thickness T2. For example, the first thickness T1 may be about 2 Å to about 20 Å, and the second thickness T2 may be about 5 Å to about 30 Å.

Referring to FIG. 3, the first capping pattern 162 may include a first non-magnetic metal. The second capping pattern 164 may include a second non-magnetic metal that is different from the first non-magnetic metal. An oxide formation energy of the first non-magnetic metal may be lower than that of the second non-magnetic metal. In this specification, the oxide formation energy may be defined as an energy of a product minus an energy of a reactant (i.e., Eoxide formation=Eproducts−Ereactants). Additionally, as the oxide formation energy is lowered, it may be easier to form the oxide and, as the oxide formation energy is higher, it may be difficult to form the oxide. For example, the first capping pattern 162 may react with oxygen more easily than the second capping pattern 164, and may be oxidized more easily than the second capping pattern 164.

For example, a thermal expansion coefficient of the first non-magnetic metal may be smaller than that of the second non-magnetic metal. Additionally, a boiling point of the second non-magnetic metal may be higher than a boiling point of the first non-magnetic metal. Accordingly, at a high temperature, the first capping pattern 162 may expand less, and the second capping pattern 164 may maintain a crystal structure thereof well.

The first capping pattern 162 may include a first portion 162a, which is adjacent to the metal oxide pattern 150, and a second portion 162b, which is disposed on the first portion 162a. The first portion 162a may be disposed between the metal oxide pattern 150 and the second portion 162b. As the first capping pattern 162 and the metal oxide pattern 150 are in contact with each other, an interface IF where the first capping pattern 162 is in contact with the metal oxide pattern 150 may correspond to the upper surface 150U of the metal oxide pattern 150. For example, the first portion 162a may be adjacent to the interface IF where the first capping pattern 162 is in contact with the metal oxide pattern 150, and the second portion 162b may be separated from the interface IF by the first portion 162a.

The first portion 162a may be formed through a high-temperature heat treatment process performed after the magnetic tunnel junction pattern MTJ is formed. For example, oxygen in the metal oxide pattern 150 may diffuse due to a high temperature heat treatment process. Oxygen in the metal oxide pattern 150 may be combined with the first non-magnetic metal that is adjacent to the interface IF where the first capping pattern 162 and the metal oxide pattern 150 are in contact with each other. As a result, the first portion 162a may be formed adjacent to the interface IF where the first capping pattern 162 and the metal oxide pattern 150 contact each other. In other words, the first portion 162a may include an oxide of the first non-magnetic metal in which the first non-magnetic metal and oxygen are combined. The second portion 162b may include only the first non-magnetic metal.

The first portion 162a may be formed to be very thin. Accordingly, a thickness of the first portion 162a may be smaller than a thickness of the second portion 162b. For example, the first portion 162a might not be identified in an image of a scanning electron microscope (SEM) or a transmission electron microscope (TEM). In addition, the first portion 162a may be identified by using electron energy loss spectroscopy (EELS) or X-ray photoelectron spectroscopy (XPS).

According to an embodiment of the present inventive concept, the first non-magnetic metal of the first capping pattern 162 may be molybdenum (Mo), and the second non-magnetic metal of the second capping pattern 164 may be rhenium (Re). In this case, the first portion 162a of the first capping pattern 162 may include molybdenum oxide.

According to an embodiment of the present inventive concept, the first capping pattern 162 may further include a metal that is different from that of the first non-magnetic metal. In this case, the first capping pattern 162 may further include any one of tantalum (Ta), tungsten (W), iridium (Ir), ruthenium (Ru), or hafnium (Hf).

Referring again to FIG. 2, a second interlayer insulating layer 180 may be provided on the first interlayer insulating layer 110. The second interlayer insulating layer 180 may cover side surfaces of the lower electrode BE, the magnetic tunnel junction pattern MTJ, and the upper electrode TE. For example, the second interlayer insulating layer 180 may include substantially the same material as the first interlayer insulating layer 110, but the present inventive concept is not limited thereto.

An upper wiring 200 may be provided on the second interlayer insulating layer 180. The upper wiring 200 may be connected to the upper electrode TE. The upper wiring 200 may be connected to the magnetic tunnel junction pattern MTJ through the upper electrode TE. The upper wiring 200 may function as the bit line BL of FIG. 1. For example, the upper wiring 200 may include at least one of a metal and/or a conductive metal nitride.

For example, the first capping pattern 162 may function as a blocking layer that suppresses diffusion of oxygen in the metal oxide pattern 150. As a result, diffusion of oxygen in the metal oxide pattern 150 to the second capping pattern 164 and the upper electrode TE may be prevented or reduced. Additionally, as the first non-magnetic metal of the first capping pattern 162 has a relatively low thermal expansion coefficient, influence of thermal expansion of the first capping pattern 162 may be relatively small. As the second non-magnetic metal of the second capping pattern 164 has a relatively high boiling point, perpendicular magnetic anisotropy may be easily maintained due to the second capping pattern 164, even at a high temperature. As a result, deterioration of the switching characteristics of the magnetic tunnel junction pattern MTJ may be prevented, and durability of the magnetic tunnel junction pattern MTJ at the high temperature may be increased. Accordingly, a heat resistance of the magnetic tunnel junction pattern MTJ may be increased.

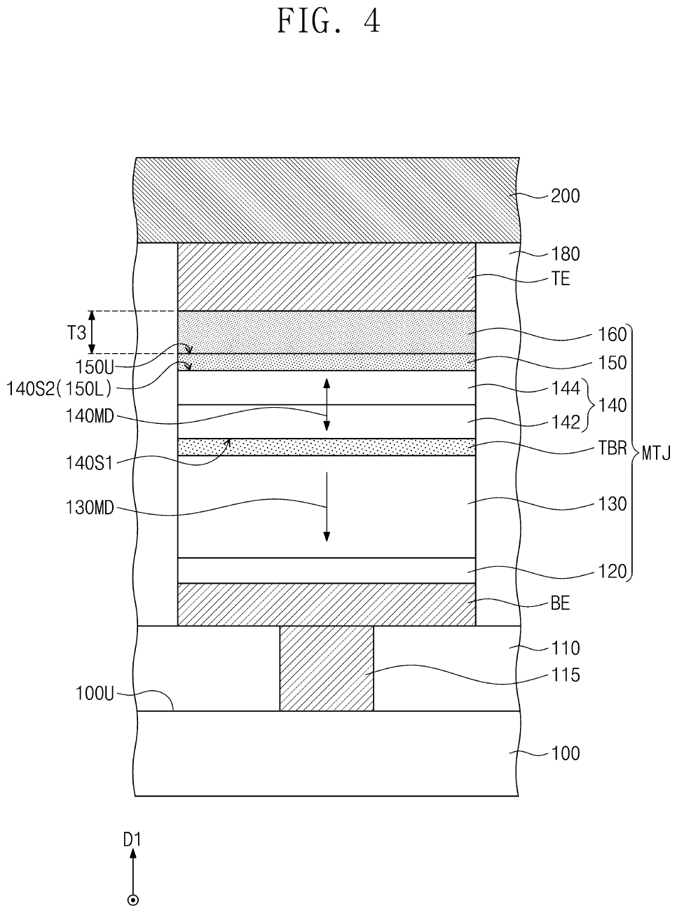

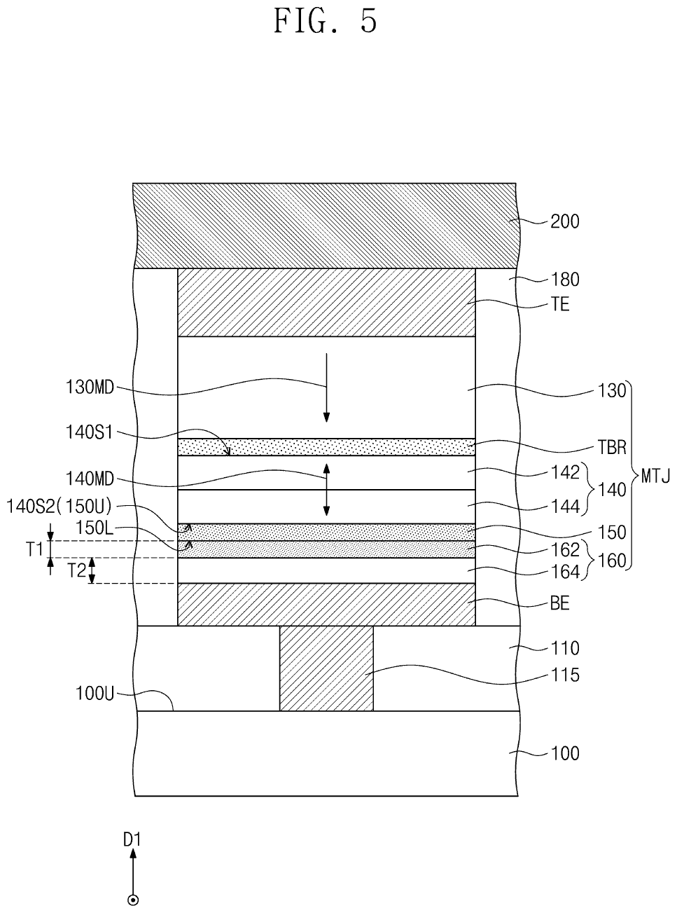

FIGS. 4 and 5 are cross-sectional views of magnetic memory devices according to embodiments of the present inventive concept.

Hereinafter, for convenience of explanation, the description of the same elements as those described with reference to FIGS. 2 and 3 will be omitted or briefly discussed and the differences will be described.

Referring to FIG. 4, a capping pattern 160 might not include a first capping pattern and a second capping pattern. For example, the capping pattern 160 may be provided as one layer. The capping pattern 160 may include a first non-magnetic metal and a second non-magnetic metal. For example, the capping pattern 160 may be an alloy formed of two or more metal elements. For example, the first non-magnetic metal may include molybdenum. For example, the second non-magnetic metal may include at least one of rhenium and/or tantalum.

The capping pattern 160 may be disposed on an upper surface 150U of the metal oxide pattern 150. For example, the capping pattern 160 may be in contact with an upper surface 150U of the metal oxide pattern 150. Accordingly, oxygen in the metal oxide pattern 150 may diffuse into the capping pattern 160. As described with reference to FIG. 3, the capping pattern 160 may include an oxide of a first non-magnetic metal adjacent to the upper surface 150U of the metal oxide 150.

The capping pattern 160 may have a certain thickness. For example, the capping pattern 160 may have a third thickness T3 in the first direction. The third thickness T3 may be substantially equal to the sum of the first thickness T1 and second thickness T2 in FIG. 2, but the present inventive concept is not limited thereto.

Referring to FIG. 5, the magnetic tunnel junction pattern MTJ may include a pinned magnetic pattern 130, a free magnetic pattern 140, and a tunnel barrier pattern TBR that is disposed between the pinned magnetic pattern 130 and the free magnetic pattern 140. The free magnetic pattern 140 may be disposed between the lower electrode BE and the tunnel barrier pattern TBR. The pinned magnetic pattern 130 may be disposed between the upper electrode TE and the tunnel barrier pattern TBR. The magnetic tunnel junction pattern MTJ may further include a capping pattern 160 that is disposed between the lower electrode BE and the free magnetic pattern 140, and a metal oxide pattern 150 that is disposed between the capping pattern 160 and the free magnetic pattern 140.

The free magnetic pattern 140 may include a first free magnetic pattern 142, which is adjacent to the tunnel barrier pattern TBR, and a second free magnetic pattern 144, which is separated from the tunnel barrier pattern TBR by the first free magnetic pattern 142. The second free magnetic pattern 144 may be adjacent to the metal oxide pattern 150. The first free magnetic pattern 142 may be disposed between the tunnel barrier pattern TBR and the second free magnetic pattern 144. The second free magnetic pattern 144 may be disposed between the first free magnetic pattern 142 and the metal oxide pattern 150.

A first surface 140S1 of the free magnetic pattern 140 may be in contact with the tunnel barrier pattern TBR. The capping pattern 160 may be disposed on a second surface 140S2 of the free magnetic pattern 140. The metal oxide pattern 150 may be disposed between the second surface 140S2 of the free magnetic pattern 140 and the capping pattern 160. For example, an upper surface 150U of the metal oxide pattern 150 may correspond to the second surface 140S2 of the free magnetic pattern 140, and a lower surface 150L of the metal oxide pattern 150 may be in contact with the capping pattern 160.

The capping pattern 160 may include a first capping pattern 162, which is adjacent to the metal oxide pattern 150, and a second capping pattern 164, which is disposed on the lower electrode BE. The first capping pattern 162 may be disposed between the metal oxide pattern 150 and the second capping pattern 164. The second capping pattern 164 may be disposed between the first capping pattern 162 and the lower electrode BE. The first capping pattern 162 and the second capping pattern 164 may be substantially the same as those described with reference to FIGS. 2 and 3. For example, the first capping pattern 162 may include a first non-magnetic metal, and the second capping pattern 164 may include a second non-magnetic metal. Additionally, the first capping pattern 162 may include an oxide of a first non-magnetic metal adjacent to the lower surface 150L of the metal oxide pattern 150 where the first capping pattern 162 is in contact with the metal oxide pattern 150.

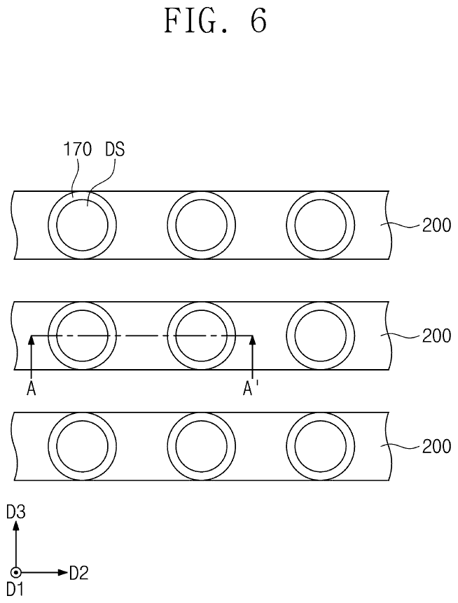

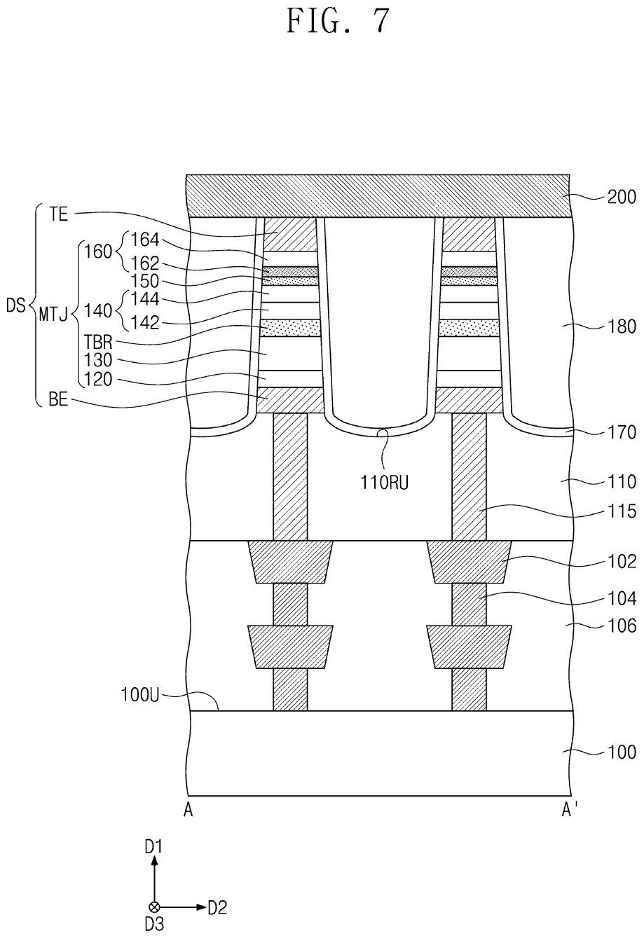

FIG. 6 is a plan view of a magnetic memory device according to an embodiment of the present inventive concept. FIG. 7 is a cross-sectional view of a magnetic memory device according to an embodiment of the present inventive concept, taken along line A-A′ of FIG. 6.

Referring to FIGS. 6 and 7, lower wirings 102 and lower contacts 104 may be provided on a substrate 100. The lower wirings 102 may be spaced apart from an upper surface 100U of the substrate 100 in a first direction D1 that is substantially perpendicular to the upper surface 100U of the substrate 100. The lower contacts 104 may be disposed between the substrate 100 and the lower wirings 102. Each of the lower wirings 102 may be electrically connected to the substrate 100 through a corresponding one of the lower contacts 104. The lower wirings 102 and lower contacts 104 may include a metal such as copper (Cu).

The selection devices SE (e.g., in FIG. 1) may be disposed in the substrate 100. For example, the selection devices SE may include field effect transistors. Each of the lower wirings 102 may be electrically connected to a corresponding one of the selection devices SE through the corresponding lower contacts 104.

A lower interlayer insulating layer 106 may be provided on the substrate 100. The lower interlayer insulating layer 106 may cover the lower wirings 102 and the lower contacts 104. An upper surface of the uppermost lower wiring 102 among the lower wirings 102 may be substantially coplanar with an upper surface of the lower interlayer insulating layer 106. For example, the upper surfaces of the uppermost lower wirings 102 among the lower wirings 102 may be disposed at substantially the same height as the upper surface of the lower interlayer insulating layer 106. In this specification, a height refers to a distance measured in the first direction D1 from the upper surface 100U of the substrate 100. For example, the lower interlayer insulating layer 106 may include silicon oxide, silicon nitride, and/or silicon oxynitride.

A first interlayer insulating layer 110 may be provided on the lower interlayer insulating layer 106. The first interlayer insulating layer 110 may cover the uppermost lower wirings 102, among the lower wirings 102, and the lower interlayer insulating layer 106.

Lower contact plugs 115 may be provided in the first interlayer insulating layer 110. The lower contact plugs 115 may be spaced apart from each other in a second direction D2 and a third direction D3 that extend parallel to the upper surface 100U of the substrate 100. The second direction D2 and the third direction D3 may intersect each other. Each of the lower contact plugs 115 may penetrate the first interlayer insulating layer 110. The lower contact plugs 115 may be connected to corresponding lower wirings 102 among the lower wirings 102. The lower contact plugs 115 may be electrically connected to a corresponding one of the selection devices SE through the corresponding lower wirings 102.

Data storage patterns DS may be provided on the first interlayer insulating layer 110. The data storage patterns DS may be spaced apart from each other in the second direction D2 and the third direction D3. The data storage patterns DS may be disposed on the lower contact plugs 115 and connected to the lower contact plugs 115, respectively.

Each of the data storage patterns DS may include a lower electrode BE, a magnetic tunnel junction pattern MTJ, and an upper electrode TE sequentially stacked on the corresponding lower contact plugs 115. The lower electrode BE may be disposed between the corresponding lower contact plugs 115 and the magnetic tunnel junction pattern MTJ. The magnetic tunnel junction pattern MTJ may be disposed between the lower electrode BE and the upper electrode TE. For example, the magnetic tunnel junction pattern MTJ may be configured substantially the same as the magnetic tunnel junction pattern MTJ described with reference to FIGS. 2 to 5.

The magnetic tunnel junction pattern MTJ may include a pinned magnetic pattern 130, a free magnetic pattern 140, and a tunnel barrier pattern TBR that is disposed between the pinned magnetic pattern 130 and the free magnetic pattern 140. The pinned magnetic pattern 130 may be disposed between the lower electrode BE and the tunnel barrier pattern TBR. The free magnetic pattern 140 may be disposed between the upper electrode TE and the tunnel barrier pattern TBR. The magnetic tunnel junction pattern MTJ may further include a seed pattern 120, which is disposed between the lower electrode BE and the pinned magnetic pattern 130, a capping pattern 160, which is disposed between the upper electrode TE and the free magnetic pattern 140, and a metal oxide pattern 150, which is disposed between the capping pattern 160 and the free magnetic pattern 140. The free magnetic pattern 140 may include a first free magnetic pattern 142, which is adjacent to the tunnel barrier pattern TBR, and a second free magnetic pattern 144, which is disposed between the first free magnetic pattern 142 and the metal oxide pattern 150. The capping pattern 160 may include a first capping pattern 162, which is disposed adjacent to the metal oxide pattern 150, and a second capping pattern 164, which is disposed between the first capping pattern 162 and the upper electrode TE.

In areas between the data storage patterns DS, an upper surface of the first interlayer insulating layer 110 may be recessed toward the substrate 100. A protective insulating layer 170 may at least partially surround each side surface of the data storage patterns DS. The protective insulating layer 170 may cover side surfaces of the lower electrode BE, the magnetic tunnel junction pattern MTJ, and the upper electrode TE. When viewed in a plan view, the protective insulating layer 170 may surround the side surfaces of the lower electrode BE, the magnetic tunnel junction pattern MTJ, and the upper electrode TE. The protective insulating layer 170 may extend from each side surface of the data storage patterns DS onto a recessed upper surface 110RU of the first interlayer insulating layer 110. The protective insulating layer 170 may cover the recessed upper surface 110RU of the first interlayer insulating layer 110 with a substantially uniform thickness. For example, the protective insulating layer 170 may include silicon nitride.

A second interlayer insulating layer 180 may be provided on the first interlayer insulating layer 110. The second interlayer insulating layer 180 may be disposed on the side surfaces of the data storage patterns DS and the protective insulating layer 170. The protective insulating layer 170 may be positioned between the side surface of each of the data storage patterns DS and the second interlayer insulating layer 180. Additionally, the protective insulating layer 170 may extend between the recessed upper surface 110RU of the first interlayer insulating layer 110 and the second interlayer insulating layer 180.

Upper wirings 200 may be provided on the second interlayer insulating layer 180. Each of the upper wirings 200 may extend in the second direction D2. The upper wirings 200 may be spaced apart from each other in the third direction D3. Each of the upper wirings 200 may be connected to data storage patterns DS that are adjacent each other in the second direction D2.

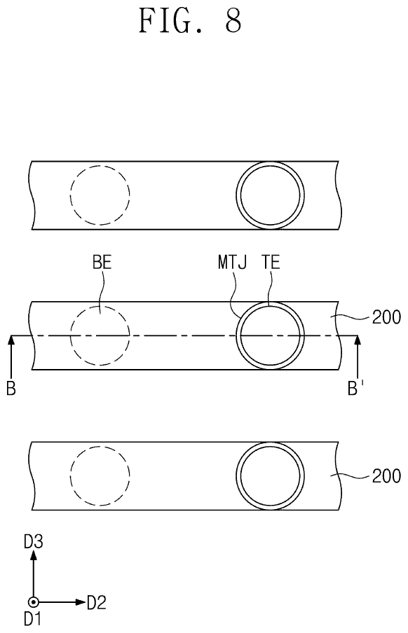

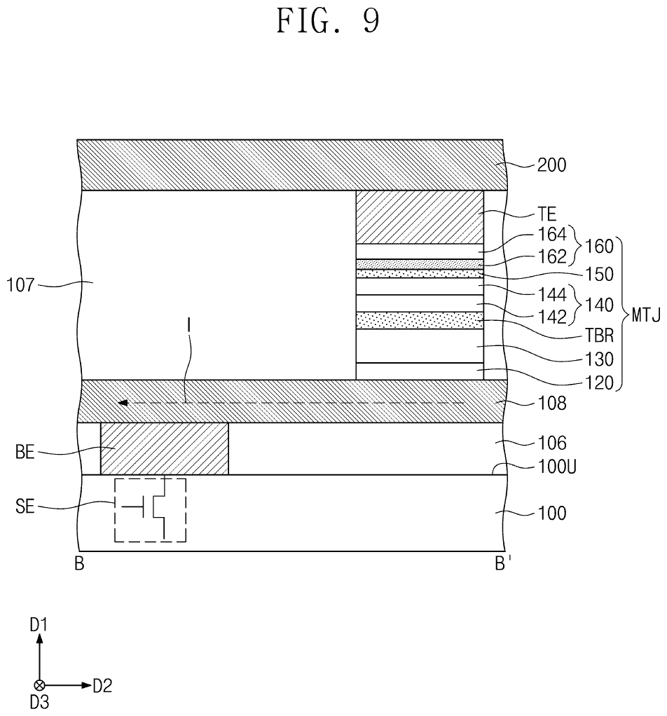

FIG. 8 is a plan view of a magnetic memory device according to an embodiment of the present inventive concept. FIG. 9 is a cross-sectional view of a magnetic memory device according to an embodiment of the present inventive concept, taken along line B-B′ of FIG. 8.

Referring to FIGS. 8 and 9, a lower electrode BE may be provided on a substrate 100. A selection device SE may be provided in the substrate 100. For example, the selection device SE may include a field effect transistor. The lower electrode BE may be electrically connected to the selection device SE.

A lower interlayer insulating layer 106 may be provided on the substrate 100. The lower interlayer insulating layer 106 may cover a side surface of the lower electrode BE. The lower interlayer insulating layer 106 may expose an upper surface of the lower electrode BE. For example, the upper surface of the lower electrode BE may be substantially coplanar with an upper surface of the lower interlayer insulating layer 106.

A conductive line 108 may be provided on the lower electrode BE. For example, the conductive line 108 may be in contact with an upper surface of the lower electrode BE and be electrically connected to the lower electrode BE. The conductive line 108 may extend on the lower interlayer insulating layer 106 in the second direction D2 that is parallel to the upper surface 100U of the substrate 100. The conductive line 108 may be formed of a multi-layer, but the present inventive concept is not limited thereto.

A magnetic tunnel junction pattern MTJ may be provided on the conductive line 108. An upper electrode TE may be provided on the magnetic tunnel junction pattern MTJ. The magnetic tunnel junction pattern MTJ may be disposed between the conductive line 108 and the upper electrode TE. The magnetic tunnel junction pattern MTJ and the upper electrode TE may vertically (e.g., in the first direction D1) overlap each other.

The magnetic tunnel junction pattern MTJ may be substantially the same as that described with reference to FIGS. 2 to 5. The magnetic tunnel junction pattern MTJ may include a pinned magnetic pattern 130, a free magnetic pattern 140, and a tunnel barrier pattern TBR that is disposed between the pinned magnetic pattern 130 and the free magnetic pattern 140. The pinned magnetic pattern 130 may be disposed between the lower electrode BE and the tunnel barrier pattern TBR. The free magnetic pattern 140 may be disposed between the upper electrode TE and the tunnel barrier pattern TBR. The magnetic tunnel junction pattern MTJ may further include a seed pattern 120, which is disposed between the lower electrode BE and the pinned magnetic pattern 130, a capping pattern 160, which is disposed between the upper electrode TE and the free magnetic pattern 140, and a metal oxide pattern 150, which is disposed between the capping pattern 160 and the free magnetic pattern 140. The free magnetic pattern 140 may include a first free magnetic pattern 142, which is adjacent to the tunnel barrier pattern TBR, and a second free magnetic pattern 144, which is disposed between the first free magnetic pattern 142 and the metal oxide pattern 150. The capping pattern 160 may include a first capping pattern 162, which is adjacent to the metal oxide pattern 150, and a second capping pattern 164, which is disposed between the first capping pattern 162 and the upper electrode TE.

The conductive line 108 may be configured to apply a spin-orbit torque to the magnetic tunnel junction pattern MTJ. For example, when the conductive line 108 includes a topological insulator, current I may flow along the conductive line 108. In this case, a spin current based on a spin Hall effect (e.g., quantum spin Hall effect) may flow in a direction that is substantially perpendicular to an upper surface of the conductive line, and thus spin-orbit torque may be applied to the magnetic tunnel junction pattern MTJ. Accordingly, the magnetization direction of the free magnetic pattern 140 may be switched by the spin-orbit torque.

An upper interlayer insulating layer 107 may be provided on the conductive line 108. The upper interlayer insulating layer 107 may cover an upper surface of the conductive line 108 and side surfaces of the magnetic tunnel junction pattern MTJ and the upper electrode TE. For example, the upper interlayer insulating layer 107 may include silicon oxide, silicon nitride, and/or silicon oxynitride. Upper wirings 200 may be provided on the upper interlayer insulating layer 107. The upper electrode TE may be electrically connected to the corresponding upper wirings 200.

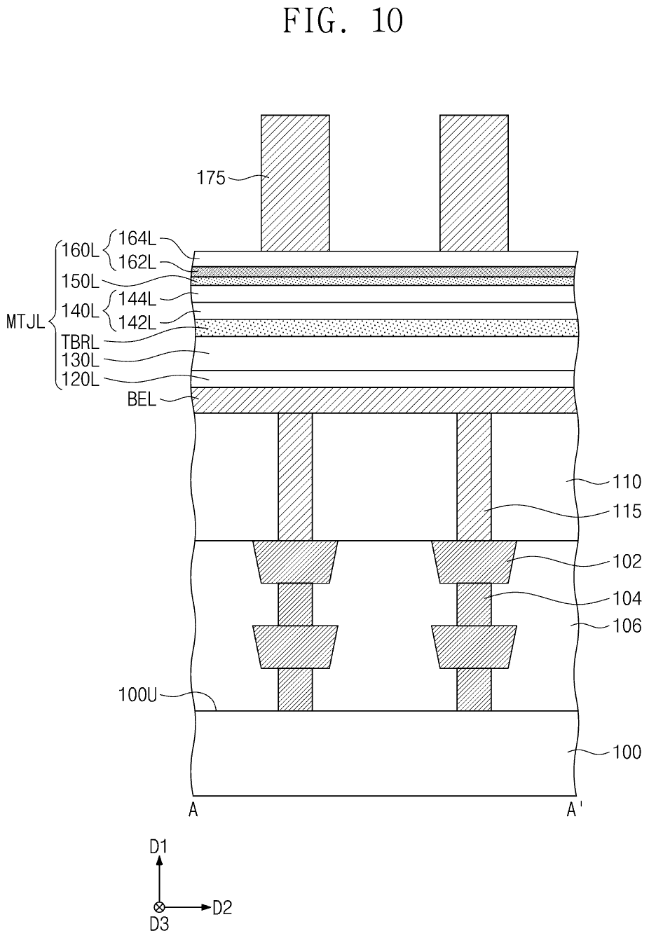

FIGS. 10 to 12 are cross-sectional views taken along line A-A′ of FIG. 6 to illustrate a method of manufacturing a magnetic memory device according to embodiments of the present inventive concept.

Referring to FIG. 10, selection devices SE (e.g., in FIG. 1) may be formed in a substrate 100. Lower wirings 102 and lower contacts 104 may be formed on the substrate 100. Each of the lower wirings 102 may be electrically connected to a corresponding one of the selection devices SE through a corresponding one of the lower contacts 104. A lower interlayer insulating layer 106 may be formed on the substrate 100 to cover the lower wirings 102 and lower contacts 104. Upper surfaces of the uppermost lower wiring 102 among the lower wirings 102 may be substantially coplanar with an upper surface of the lower interlayer insulating layer 106.

A first interlayer insulating layer 110 may be formed on the lower interlayer insulating layer 106. Lower contact plugs 115 may be formed in the first interlayer insulating layer 110. Each of the lower contact plugs 115 may penetrate the first interlayer insulating layer 110 and be connected to a corresponding lower wiring 102 among the lower wirings 102. A method of forming the lower contact plugs 115 may include forming lower contact holes that penetrate the first interlayer insulating layer 110, forming a lower contact layer, which fills the lower contact holes, on the first interlayer insulating layer 110, and planarizing the lower contact layer until the upper surface of the first interlayer insulating layer 110 is exposed.

A lower electrode layer BEL and a magnetic tunnel junction layer MTJL may be sequentially formed on the first interlayer insulating layer 110. The magnetic tunnel junction layer MTJL may include a seed layer 120L, a pinned magnetic layer 130L, a tunnel barrier layer TBRL, a free magnetic layer 140L, a metal oxide layer 150L, and a capping layer 160L sequentially stacked on the lower electrode layer BEL. The free magnetic layer 140L may include a first free magnetic layer 142L and a second free magnetic layer 144L that are sequentially stacked on the tunnel barrier layer TBRL. The capping layer 160L may include a first capping layer 162L, which is adjacent to the metal oxide layer 150L, and a second capping layer 164L, which is stacked on the first capping layer 162L. For example, the lower electrode layer BEL and the magnetic tunnel junction layer MTJL may be formed through sputtering, chemical vapor deposition, or atomic layer deposition processes.

Conductive mask patterns 175 may be formed on the magnetic tunnel junction layer MTJL. The conductive mask patterns 175 may define a region where magnetic tunnel junction patterns, which will be described later, will be formed. The conductive mask patterns 175 may include at least one of a metal (e.g., Ta, W, Ru, Ir, etc.) and/or conductive metal nitride (e.g., TiN).

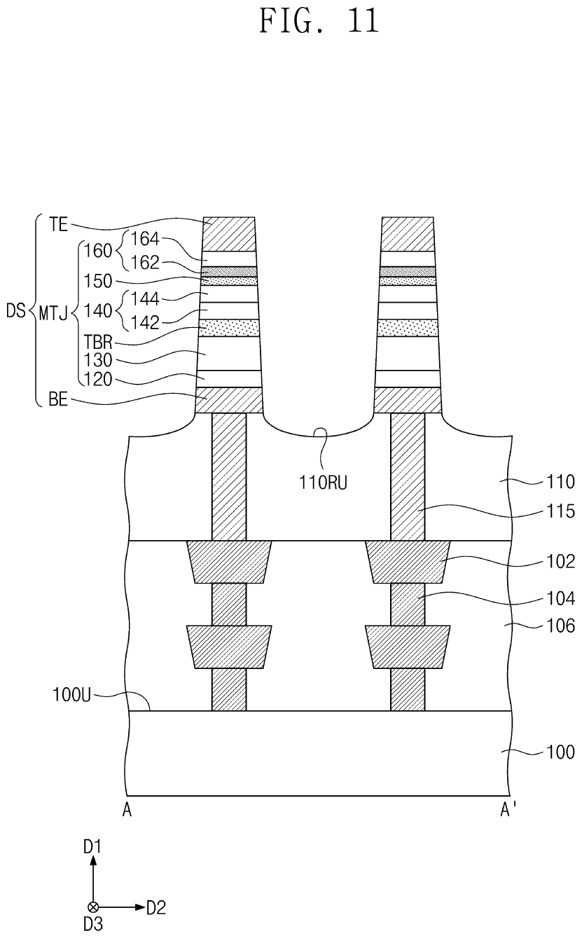

Referring to FIG. 11, the magnetic tunnel junction layer MTJL and the lower electrode layer BEL may be etched by using the conductive mask patterns 175 as an etch mask. Accordingly, a magnetic tunnel junction pattern MTJ and a lower electrode BE may be formed on the first interlayer insulating layer 110. The lower electrode BE may be connected to the corresponding contact plugs 115, and a magnetic tunnel junction pattern MTJ may be formed on the lower electrode BE.

Etching the magnetic tunnel junction layer MTJL may include sequentially etching the capping layer 160L, the non-magnetic layer 150L, the free magnetic layer 140L, the tunnel barrier layer TBRL, the pinned magnetic layer 130L, and the seed layer 120L by using the conductive mask patterns 175 as an etch mask. As a result, a seed pattern 120, a pinned magnetic pattern 130, a tunnel barrier pattern TBR, a free magnetic pattern 140, a metal oxide pattern 150, and a capping pattern 160, which are sequentially stacked on the lower electrode BE, may be formed. The free magnetic pattern 140 may include a first free magnetic pattern 142 and a second free magnetic pattern 144 that are formed by etching the first free magnetic layer 142L and the second free magnetic layer 144L. The capping pattern 160 may include a first capping pattern 162 and a second capping pattern 164 that are formed by etching the first capping layer 162L and the second capping layer 164L.

For example, the etching process for etching the magnetic tunnel junction layer MTJL and the lower electrode layer BEL may be an ion beam etching process that uses an ion beam. The ion beam may include inert ions. Through an ion beam etching process, an upper surface of the first interlayer insulating layer 110 may be recessed on both sides of the magnetic tunnel junction pattern MTJ. Accordingly, the first interlayer insulating layer 110 may have an upper surface 110RU that is recessed on both sides (e.g., opposing sides) of the magnetic tunnel junction pattern MTJ.

After the ion beam etching process, a portion of each of the conductive mask patterns 175 may remain on the magnetic tunnel junction pattern MTJ. A portion of each of the conductive mask patterns 175 may function as an upper electrode TE. That is, each of the conductive mask patterns 175 may be formed as an upper electrode TE. The upper electrode TE, magnetic tunnel junction pattern MTJ, and lower electrode BE may constitute each of data storage patterns DS.

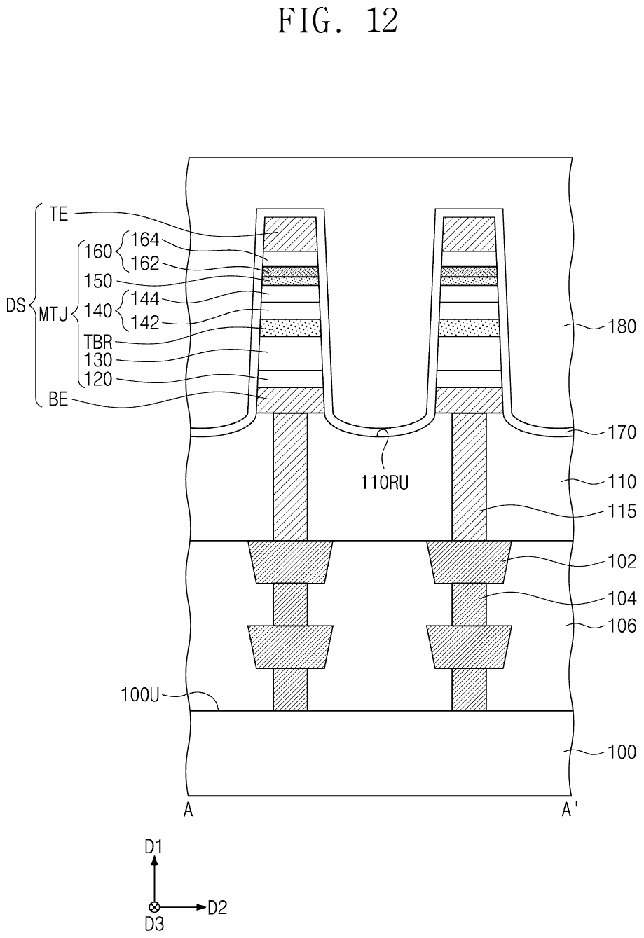

Referring to FIG. 12, a protective insulating layer 170 may be formed on the first interlayer insulating layer 110 to cover the data storage patterns DS. The protective insulating layer 170 may be formed to cover upper and side surfaces of each of the data storage patterns DS with a substantially uniform thickness. The protective insulating layer 170 may extend along the recessed upper surface 110RU of the first interlayer insulating layer 110. A second interlayer insulating layer 180 may be formed on the protective insulating layer 170 and may cover the data storage patterns DS.

Referring again to FIG. 7, a portion of the second interlayer insulating layer 180 and the protective insulating layer 170 may be removed, and an upper surface of the upper electrode TE of each of the data storage patterns DS may be exposed. An upper wiring 200 may be formed on the second interlayer insulating layer 180 and may cover the exposed upper surface of the upper electrode TE. The upper wiring 200 may be electrically connected to the upper electrode TE.

According to embodiments of the present inventive concept, the magnetic tunnel junction pattern MTJ may include a metal oxide pattern 150 and a capping pattern 160 sequentially stacked on one side of the free magnetic pattern 140. The capping pattern 160 may include a first capping pattern 162 and a second capping pattern 164 that is disposed on the first Additionally, the first capping pattern 162 may include a first capping pattern 162. non-magnetic metal, and the second capping pattern 164 may include a second non-magnetic metal that is different from the first non-magnetic metal. The first capping pattern 162 may function as a blocking layer that suppresses diffusion of oxygen in the metal oxide pattern 150. As a result, diffusion of oxygen in the metal oxide pattern 150 into the second capping pattern 164 may be prevented or reduced. Additionally, as the first non-magnetic metal of the first capping pattern 162 has a relatively low thermal expansion coefficient, influence of thermal expansion of the first capping pattern 162 may be small. As the second non-magnetic metal of the second capping pattern 164 has a relatively high boiling point, perpendicular magnetic anisotropy may be easily maintained due to the second capping pattern 164, even at a relatively high temperature. As a result, deterioration of the switching characteristics of the magnetic tunnel junction pattern MTJ may be prevented, and durability of the magnetic tunnel junction pattern MTJ at the high temperature may be increased. Accordingly, the heat resistance of the magnetic tunnel junction pattern MTJ may be increased.

The magnetic memory device according to embodiments of the present inventive concept may include the first capping pattern, which is adjacent to the metal oxide pattern, and the second capping pattern, which is disposed on the first capping pattern. The first capping pattern may function as the blocking layer that suppresses the diffusion of oxygen in the metal oxide pattern. As a result, the diffusion of oxygen, which is in the metal oxide pattern, into the second capping pattern may be prevented or reduced. Additionally, as the first non-magnetic metal of the first capping pattern has the relatively low thermal expansion coefficient, the influence of thermal expansion of the first capping pattern may be small. As the second non-magnetic metal of the second capping pattern has the relatively high boiling point, the perpendicular magnetic anisotropy may be easily maintained due to the second capping pattern, even at high temperatures. As a result, the deterioration of the switching characteristics of the magnetic tunnel junction pattern may be prevented, and durability of the magnetic tunnel junction pattern at high temperatures may be increased. Accordingly, the heat resistance of the magnetic tunnel junction pattern may be increased.

While the present inventive concept has been described with reference to embodiments thereof, it will be understood by those of ordinary skill in the art that various changes in form and details may be made thereto without departing from the spirit and scope of the present inventive concept.

What is claimed is:

1. A magnetic memory device comprising:
a pinned magnetic pattern and a free magnetic pattern stacked on a substrate;
a tunnel barrier pattern between the pinned magnetic pattern and the free magnetic pattern;
a capping pattern on the free magnetic pattern; and
a metal oxide pattern between the free magnetic pattern and the capping pattern,
wherein the capping pattern includes a first capping pattern and a second capping pattern that is on the first capping pattern,
wherein the first capping pattern includes a first non-magnetic metal,
wherein the second capping pattern includes a second non-magnetic metal, and
wherein the first capping pattern includes an oxide of the first non-magnetic metal that is adjacent to an interface that is between the metal oxide pattern and the first capping pattern.

2. The magnetic memory device of claim 1, wherein a thickness of the first capping pattern is smaller than a thickness of the second capping pattern.

3. The magnetic memory device of claim 1, wherein the first non-magnetic metal is molybdenum (Mo), and the second non-magnetic metal is rhenium (Re).

4. The magnetic memory device of claim 1, wherein an oxide formation energy of the first non-magnetic metal is lower than an oxide formation energy of the second non-magnetic metal.

5. The magnetic memory device of claim 1, wherein the first capping pattern further includes one of tantalum (Ta), tungsten (W), iridium (Ir), ruthenium (Ru), or hafnium (Hf).

6. The magnetic memory device of claim 1, wherein the metal oxide pattern includes one of magnesium (Mg), tungsten (W), tantalum (Ta), titanium (Ti), or hafnium (Hf).

7. The magnetic memory device of claim 1, wherein each of the pinned magnetic pattern and the free magnetic pattern has a magnetization direction that is perpendicular to an interface that is between the free magnetic pattern and the tunnel barrier pattern.

8. The magnetic memory device of claim 1, wherein the second non-magnetic metal has a higher boiling point than that of the first non-magnetic metal.

9. The magnetic memory device of claim 1, further comprising:
a lower electrode between the substrate and the pinned magnetic pattern; and
an upper electrode on the capping pattern, and
wherein the pinned magnetic pattern is disposed between the substrate and the tunnel barrier pattern.

10. The magnetic memory device of claim 1, further comprising:
a lower electrode between the substrate and the pinned magnetic pattern; and
an upper electrode on the capping pattern,
wherein the free magnetic pattern is disposed between the substrate and the tunnel barrier pattern, and
wherein the capping pattern is disposed between the substrate and the free magnetic pattern.

11. A magnetic memory device comprising:
a pinned magnetic pattern and a free magnetic pattern stacked on a substrate;
a tunnel barrier pattern between the pinned magnetic pattern and the free magnetic pattern;
a first capping pattern and a second capping pattern stacked on the free magnetic pattern; and
a metal oxide pattern between the free magnetic pattern and the first capping pattern,
wherein the first capping pattern includes molybdenum (Mo), and
wherein the second capping pattern includes rhenium (Re).

12. The magnetic memory device of claim 11, wherein the first capping pattern and the metal oxide pattern are in contact with each other to form an interface therebetween, and
wherein the first capping pattern further includes molybdenum oxide that is adjacent to the interface that is between the first capping pattern and the metal oxide pattern.

13. The magnetic memory device of claim 11, wherein the first capping pattern has a thickness of 2 Å to 20 Å, and
wherein the second capping pattern has a thickness of 5 Å to 30 Å.

14. The magnetic memory device of claim 11, wherein the first capping pattern further includes one of tantalum (Ta), tungsten (W), iridium (Ir), ruthenium (Ru), or hafnium (Hf).

15. The magnetic memory device of claim 11, wherein the free magnetic pattern includes:
a first free magnetic pattern that is adjacent to the tunnel barrier pattern; and
a second free magnetic pattern that is adjacent to the metal oxide pattern and in contact with the first free magnetic pattern.

16. The magnetic memory device of claim 11, wherein the first capping pattern is disposed between the metal oxide pattern and the second capping pattern, and
wherein the first capping pattern is in contact with the metal oxide pattern and the second capping pattern.

17. A magnetic memory device comprising:
a lower electrode on a substrate;
a pinned magnetic pattern and a free magnetic pattern stacked on the lower electrode;
a tunnel barrier pattern between the pinned magnetic pattern and the free magnetic pattern;
a capping pattern on the tunnel barrier pattern;
a metal oxide pattern between the capping pattern and the tunnel barrier pattern; and
an upper electrode on the capping pattern,
wherein the capping pattern includes:
a first capping pattern including a first non-magnetic metal; and
a second capping pattern including a second non-magnetic metal on the first capping pattern,
wherein an oxide formation energy of the first non-magnetic metal is lower than an oxide formation energy of the second non-magnetic metal, and
wherein a thickness of the first capping pattern is smaller than a thickness of the second capping pattern.

18. The magnetic memory device of claim 17, wherein the first non-magnetic metal includes molybdenum (Mo), and
wherein the second non-magnetic metal includes rhenium (Re).

19. The magnetic memory device of claim 17, wherein the first capping pattern includes an oxide of the first non-magnetic metal that is adjacent to an interface that is between the first capping pattern and the metal oxide pattern.

20. The magnetic memory device of claim 17, wherein the second non-magnetic metal has a higher boiling point than that of the first non-magnetic metal.
